(19) United States
(12) Patent Application Publication
(10) Pub. No.: US 2021/0320253 A1
(43) Pub. Date: Oct. 14, 2021

(54) A METHOD FOR FORMING A FILM OF A PEROVSKIT-LIKE MATERIAL

(71) Applicant: JOINT STOCK COMPANY KRASNOYARSK HYDROPOWER PLANT (JSC KRASNOYARSK HPP), Divnogorsk (RU)

(72) Inventors: Evgenij Alekseevich GUDILIN, Moscow (RU); Aleksej Borisovich TARASOV, Moscow (RU); Aleksej Yur'evich GRISHKO, Volgograd (RU); Yasha Mihajlovich FINKEL'BERG, Moscow (RU)

(21) Appl. No.: 17/272,506

(22) PCT Filed: Dec. 26, 2018
(86) PCT No.: PCT/RU2018/000875

§ 371 Date: Mar. 1, 2021

(30) Foreign Application Priority Data
Sep. 20, 2018 (RU) 2018133408

(51) Int. Cl. H01L 51/00

(52) U.S. Cl. CPC H01L 51/0007; H01L 51/4213; H01L 51/0028

(57) ABSTRACT

To improve the quality of semiconductor films, to reduce the culling of finished products, the parameters of which do not meet the established requirements in the method of forming a semiconductor film of a perovskite-like material, a layer of a perovskite-like material or a precursor of a perovskite-like material of the predefined thickness is deposited on the substrate, followed by halogen layer until liquefaction of the layer, then the halogen is gradually removed from the substrate until it is completely removed, ensuring the gradual crystallization of the perovskite-like material on a substrate to form perovskite-like material grains larger than perovskite-like material grains of the original film.

### TECHNICAL FIELD

The invention relates to methods for forming semiconductor layers and may be used for post-processing of films of semiconductor materials in order to improve crystallinity, improve the electrical and photoelectric properties of the light absorbing layer in the production of photoelectric converters.

### BACKGROUND

Various methods for post-processing thin films of compounds ABX₃ are known from the prior art, where A stands for CH₃NH₃⁺ or (NH₂)₂CH⁺ or C(NH₂)₃⁺ or Cs⁺ or Rb⁺ or their mixture, B=Sn₂⁺ or Pb₂⁺, or their mixture, in particular, with the addition of Bi and Cu, and as component X can act halide ions (Cl⁻ or Br⁻ or I⁻ or their mixture). More generally, other cations can also act as components A and B, so that their total charge and amounts to +3 and balances the charge of the anion.

The most common method of post-processing is annealing in the temperature range of 100-120° C., and sometimes includes short-term high-temperature annealing at temperatures above 120° C.

The article [Saliba, Michael, et al. “Influence of thermal processing protocol upon the crystallization and photovoltaic performance of organicinorganic lead trihalide perovskites.” The Journal of Physical Chemistry C 118.30 (2014): 17171-17177.] shows that annealing of CH₃NH₃PbI₃ films at a temperature of 100° C. for 45 minutes under dry nitrogen atmosphere and improves the photoelectric properties of this layer.

In the article [Xiao Z. et al. Solvent Annealing of Perovskite-Induced Crystal Growth for Photovoltaic-Device Efficiency Enhancement//Adv. Mater. 2014. Vol. 26, No. 37. P. 6503-6509] it was shown that annealing in dimethylformamide vapor, compared to dry annealing, leads to the increase of the grain size, reduction of concentration of defects, an increase lifetime of charge carriers and their mean free path, an increased efficiency of carrier injection into electron and hole-conducting layers. In this work, annealing was performed at the temperature of 100° C. for 60 min.

The disadvantages of the above methods are: 1) the need to maintain a relatively high temperature, 2) the long duration of the post-processing stage.

The method of post-processing of perovskite films in methylamine vapor (MA) is known—[Zhao T. et al. Design rules for the broad application of fast (1 s) methylamine vapor based, hybrid perovskite post deposition treatments//RSC Adv. 2016. Vol. 6, No. 33. P. Pp 27475-27484]. When using this reagent, a rapid reversible decomposition of hybrid organic-inorganic materials accompanied with the formation of a liquid phase, from which crystallization of the initial or related to initial compounds is possible after removal of the MA vapor. A significant disadvantage of this approach is that, when processed with MA vapor, there is a substitution of the organic component that is part of the original material with the component introduced through the gas phase during processing. Since the functional properties of the final material substantially depend on the ratio of cations in the perovskite-like compound, the treatment with MA vapor cannot be fully applied to the post-processing of films of perovskite-like compounds with mixed A-cation composition.

The closest to the proposed invention is a method similar to the described above for post-processing of perovskite films in formamidine (FA) vapors—[Zhou, Yuanyuan, et al. “Exceptional morphology-preserving evolution of formamidinium lead triiodide perovskite thin films via organic-cation displacement.” Journal of the American Chemical Society 138.17 (2016): 5535-5538.] When using this reagent, there is a rapid reversible destruction of hybrid organic-inorganic materials with the formation of a liquid phase, from which crystallization of the initial or related initial compounds is possible after removal of the FA vapor. A significant disadvantage of this approach is that, when processing with FA vapor, there is also a substitution of the organic component that is part of the original material with the component introduced through the gas phase during processing. Since the functional properties of the final material substantially depend on the ratio of cations in the perovskite-like compound, the treatment with MA vapor also cannot be fully applied to the post-processing of films of perovskite-like compounds of a composition mixed by cation A.

Thus, currently known methods of post-processing the light-absorbing layer of perovskite solar cells in order to increase its electrical and photoelectric properties require annealing of this layer for a long time at relatively high temperatures or incompatible with mixed-cation compositions.

A technical problem that exist in the present state of the art is the need for post-processing by continuous annealing at relatively high temperatures (100-120° C.) of thin films of light-absorbing materials with a perovskite-like ABX₃ composition, where A=CH₃NH₃⁺ or (NH₂)₂CH⁺ or C(NH₂)₃⁺ or Cs⁺ or Rb⁺ or their mixture; B=Sn₂⁺ or Pb₂⁺, or their mixture, probably doped with Bi and Cu; X=Cl⁻ or Br⁻ or I⁻ or their mixture to achieve the required quality of coatings, giving them the required electrical and photoelectric properties after their production.

The technical result achieved when using the invention is the improvement of the quality of semiconductor films, reducing the culling of complete devices, the parameters of which do not meet the established requirements. In addition, the invention provides the possibility of increasing the grain size, improving the electrical, photoelectric properties of thin films of light-absorbing materials with a perovskite-like structure of the ABX₃ composition. Improving the physical structure of the films occurs without unacceptable changes in the chemical composition and properties of the original films, which is unattainable when using previously known reagents, for example, methylamine or formamidine.

An additional technical result is an acceleration of the post-treatment process, leading to an improvement in the morphology, electrical, photoelectric properties of thin films of light-absorbing materials with a perovskite-like ABX₃ composition compared to methods based on high temperature treatments.

An additional technical result is the applicability of the approach described in the present application to perovskite-like compounds composed of mixed cations as compared with methods based on the effect of vapor on the films being treated with methylamine or formamidine.

### DISCLOSURE OF THE INVENTION

The technical result is achieved in that the method of forming a semiconductor film of a perovskite-like material, a substrate of a perovskite-like material or a precursor of a perovskite-like material of a predetermined thickness is applied onto the substrate, after that a halogen is applied to the layer until liquefaction of the layer, after that the halogen is gradually removed from the substrate, ensuring a gradual crystallization of the perovskite-like material on the substrate with the formation of grains of a perovskite-like material of a size larger than in the original film. In the particular case of the implementation of the method, the semiconductor material layer has the chemical composition of ABX₃, where at least one of the CH₃NH₃⁺ or (NH₂)₂CH⁺ or C(NH₂)₃⁺ or Cs⁺ or Rb⁺ cations or their mixture is used as component A, as component B is used at least one of the elements Pb, Sn, Bi, Cu, Ge, Ca, Sr, Ti or their mixture, and at least one of the halogens Cl⁻ or Br⁻ or I⁻ or their mixture is used as the component X, herein the film to be treated may contain the components A, B, X of the compound ABX₃, in particular, contained within compounds other than final ABX₃ perovskite—in this case the exposure of the initial films to the halogen may result in the formation of perovskite-like material. In the particular case of the invention, the rate of halogen removal from the substrate is controlled, while the initial rate of halogen removal from the substrate can be selected to ensure the formation in the layer of crystallization centers with a predetermined number of crystallization centers per unit area of the substrate. At the same time, the precursor of a perovskite-like material is a compound or a mixture of a perovskite-like material with other substances, for example, in the form of an adduct (the product of an addition reaction between two compounds) of a perovskite-like material with solvents. When treating a precursor of perovskite-like material with a halogen, side substances chemically bound within the precursor are released and then removed together with the halogen. Halogen can be introduced into the reaction cell with the sample through the gas phase or as a pure liquid halogen or as a solution containing halogen. When introducing the halogen from the gas phase, a gas mixture containing halogen and/or component A vapor may be used. When implementing the method, during the processing of the semiconductor film with halogens, the substrate and/or solution and/or the gas mixture containing halogens can be heated, and the halogen-containing reaction mixture may be supplied under pressure. Removal of excess halogens and/or reaction products can occur when using heat treatment, including cooling or heating, or purging a reaction cell with a semiconductor film with inert gas or by keeping under reduced pressure immediately after exposure of the film of the semiconductor material to halogen. During the formation of the photoelectric layer, in the particular case of the implementation of the method, the formation of grains ranging in size from 100 nm to 100 pm is provided, and iodine vapor with a partial pressure of 0.000001 atm to 0.99 atm is used to liquefy the layer. For a uniform distribution of the grains on the substrate with the formation of a layer of optimal thickness, the grain sizes are set from 0.9 to 1.1 of the average layer thickness after removal of halogen, or from 0.45 to 0.55 of the average layer thickness after removal of halogen.

As one of the embodiments of the invention, a thin film of a light-absorbing material with a perovskite-like structure of ABX₃ composition on a carrier substrate is exposed to molecular iodine coming from the gas phase or from a solution, resulting in a reversible decomposition of the ABX₃ phase with the formation of liquid AXₙ in equilibrium with BX₂. In particular, when using only ABI₃ in the perovskite-like structure, AIₙ liquid is formed in equilibrium with BI₂.

Then, when the partial pressure of iodine is lowered to a predetermined level or in case of complete elimination of contact of iodine with the substrate, for example, by increasing the substrate temperature or purging with a stream of a halogen-free gas, iodine is removed at a certain rate from the AXₙ liquid in equilibrium with BX₂ and the ABX₃ phase crystallizes. The rate of removal of iodine solution or a gas mixture containing iodine vapor determines the crystallization rate of ABX₃, which determines the crystallinity and, consequently, the electrical and photoelectric properties of this material.

The term pero perovskite-like structure, in the content of this application, refers to both the crystal structure of the perovskite mineral (CaTiO₃) and the crystal structures with certain structural deviations (distorted structure of the perovskite), for example, with a lower lattice symmetry (for example, tetragonal syngony) or crystal structures containing perovskite layers alternating with any other layers (for example, the phases of Aurivillius, the Ruddlesden-Popper phase, the Dion-Jacobson phase). Perovskite-like compounds are meant to be compounds with a perovskite-like structure. Thin films in this application refers to films with a thickness of from 50 nm to 3 μm.

As it is known, the grains boundaries are a potential source of defects that have a negative impact on the functional properties of semiconductor materials. An increase in the grain size leads to an increase in the volume-to-surface ratio and a decrease in the number of grain boundaries, which ultimately leads to an improvement of the electrical and photoelectric properties of the material.

The possibility of using lower temperatures and shorter post-processing times for the ABX₃ light absorbing material are based on the ability of the ABX₃ compound to interact with molecular iodine to form the highly reactive liquid phase of composition AXₙ, upon contact with which intensive mass transfer of the ABX₃ compound occurs, promoting its recrystallization.

In the more general case, the formula ABX₃ can be understood as compounds in which X is a halide, A, B are metal cations or organic cations such that the total charge of cations A and B is +3, i.e. doping with other inorganic elements or organic cations is allowed, including heterovalent doping. In addition, this approach is not specific to compounds of the ABX₃ with a perovskite-like structure of a given composition and can be extended to compounds with a crystal structure different from the perovskite-like and chemical composition other than ABX₃.

The possibility of implementing the proposed method in various embodiments with the achievement of the technical result is confirmed by the examples below:

Example 1: A film of composition CH₃NH₃PbI₃, obtained by deposition from a solution in dimethyl sulfoxide with a thickness of 300 nm, was treated with iodine vapor in a closed glass vessel, at the bottom of which crystalline iodine was placed. The treatment was carried out for 3 minutes at room temperature, after which the initial film was removed from the atmosphere of iodine and examined by scanning electron microscopy. An analysis of micrographs revealed an increase in the average grain size from ˜50 nm to ˜200 nm

Example 2: analogously to example A (example 1), but the treatment was carried out while maintaining the reaction vessel at T=40° C. for 1 minute. An analysis of micrographs revealed an increase in the average grain size from ˜50 nm to ˜300 nm

Example 3: analogously to example A, the process was carried out while maintaining the temperature of the substrate at T=60° C., which was treated for 3 minutes with a gas stream blown through crystalline iodine kept at T=40° C. An analysis of the micrographs of the film revealed an increase in the average grain size from ˜50 nm to ˜400 nm.

Example 4: analogously to example A, but the films of composition Cs_{0.05} (MA_{0.17}FA_{0.83}) PbI₃ were subjected to treatment at T=40° C. for 3 minutes. An analysis of micrographs revealed an increase in the average grain size from ˜50 nm to ˜200 nm, an analysis of the phase composition of the film showed that the ratio of cations A in it did not change compared with the initial one.

Despite the fact that the analytical dependence of grain sizes and their properties on the halogen concentration in the initial solution and the halogen removal rate has not been found, the required parameters can be determined empirically.

In addition, it is revealed that a significant, 3 times or more, decrease in the halogen removal rate after the formation of the required number of crystallization centers per unit volume of the layer or per unit surface area of the substrate, ensures the formation of grains of a stable size in a given amount.

1. A method of forming a semiconductor film of a perovskite-like material, wherein a layer of perovskite-like material of predetermined thickness is deposited on a substrate and exposed to halogen until partial liquefaction of the layer, and then the halogen is gradually removed from the substrate, ensuring gradual crystallization perovskite-like material on a substrate with the formation of grains of a perovskite-like material of a size larger than size of grains of a perovskite-like material in the initial layer.

2. The method according to claim 1, wherein the layer of the perovskite-like material is made in the form of a precursor of the perovskite-like material, which contains, in addition to the components of the desired perovskite-like material, other chemicals

3. The method according to claim 1, wherein the precursor contains solvent molecules.

4. The method according to claim 1, wherein the semiconductor material layer has a chemical composition of ABX₃, where at least one of the CH₃NH₃⁺ or (NH₂)₂CH⁺ or C(NH₂)₃⁺ or Cs⁺ or Rb⁺ cations or their mixture is used as component A, at least one of the elements Pb, Sn, Bi, Cu, Ge, Ca, Sr, Ti or their mixture is used as component B and as a component X is used at least one of halogens Cl⁻ or Br⁻ or I⁻ or their mixture.

5. The method according to claim 1, wherein the film to be treated contains in the elemental composition the components of the ABX₃ compound.

6. The method according to claim 1, wherein the rate of halogen removal from the substrate is regulated.

7. The method according to claim 6, wherein the initial rate of halogen removal from the substrate is chosen to ensure the formation in the layer of crystallization centers with a predetermined number of crystallization centers per unit area of the substrate.

8. The method according to claim 1, wherein the halogen on the substrate is separated from the gas phase

9. The method according to claim 1, wherein substrate is exposed to halogen that is used in the form of pure liquid halogen or in the form of a solution containing halogen.

10. The method according to claim 4, wherein applying halogen from the gas phase, uses a gas mixture containing a vapor of component A.

11. The method according to claim 7, wherein during the processing of the semiconductor film with halogens, the substrate and/or the solution and/or the gas mixture containing halogens is heated

12. The method according to claim 11, wherein the halogen-containing reaction mixture is supplied under pressure

13. The method according to claim 6, wherein the removal of excess halogens and/or reaction products is performed while using temperature treatment (cooling or heating) or purging a semiconductor film by a controlled flow of inert gas or by exposure in a low pressure directly after affection of halogens to the film on a perovskite-like film material.

14. The method according to claim 1, wherein during the formation of the photoelectric layer, the formation of grains ranging in size from 100 nm to 100 μm is provided, and iodine vapor with a partial pressure of 0.000001 atm to 0.99 atm is used to liquefy the layer.
